(19) United States
(12) Patent Application Publication
(10) Pub. No.: US 2022/0159386 A1
(43) Pub. Date: May 19, 2022

(54) PIEZOELECTRIC SPEAKER AND MANUFACTURING METHOD THEREFOR

(71) Applicant: ECO DM LAB CO., LTD., Cheongju-si Chungcheongbuk-do (KR)

(72) Inventors: Man Soon YOON, Cheongju-si Chungcheongbuk-do (KR); Young Min PARK, Pohang-si Gyeongsangbuk-do (KR)

(21) Appl. No.: 17/439,398

(22) PCT Filed: Mar. 12, 2020
(86) PCT No.: PCT/KR2020/003450

§ 371 Date: Sep. 14, 2021

(30) Foreign Application Priority Data
Mar. 15, 2019 (KR) 10-2019-0030139
Aug. 20, 2019 (KR) 10-2019-0101607

(51) Int. Cl. H04R 17/00; H01L 41/273; H01L 41/277; G10K 9/122

(52) U.S. Cl. CPC H04R 17/005; G10K 9/122; H01L 41/277; H01L 41/273

(57) ABSTRACT

Disclosed are a piezoelectric speaker employing a piezoelectric device having a through-hole and a method for manufacturing the same. The piezoelectric speaker includes a piezoelectric device including a stacked body having through-holes and electrodes formed at the stacked body, an adhesive layer disposed on the lower surface of the piezoelectric device, and a diaphragm attached to the piezoelectric device by the adhesive layer. The through-holes are arranged to decrease in size as they move away from the center of the piezoelectric element. The through-holes have a symmetrical arrangement with respect to the center, and the inner surface of each through-hole has a curved edge. The structure and arrangement of these through-holes do not cause cracks during the sintering process.

### TECHNICAL FIELD

The present inventive concept is related to piezoelectric speaker, more particularly to piezoelectric speaker using a piezoelectric device having a plurality of through-holes and method of manufacturing the same.

### BACKGROUND ART

As customer demand is increasingly focused on mobile and miniaturization, piezoelectric speakers are attracting attention as an alternative to the existing speakers using magnetic coils. Since the piezoelectric speaker is thin and light, and has low power consumption, it can be applied to various uses such as portable electronic devices, ultra-thin TVs, and automobiles.

In general, piezoelectric speaker has a structure in which a piezoelectric device is attached to a polymer or metal diaphragm with an adhesive. The shape deformation of the piezoelectric device occurs by applying an alternating voltage to both surfaces of the piezoelectric device, and a sound is generated by transmitting the shape deformation of the piezoelectric device to the metal diaphragm. The piezoelectric speaker has a structure in which a piezoelectric device is attached to an upper portion of a metal diaphragm, and the metal diaphragm is displaced by a signal applied to the piezoelectric device to generate sound.

In the basic structure of the piezoelectric speaker, the sound velocity and density of the metal diaphragm are different from those of air, so there is a big difference between the impedance of the metal diaphragm and the acoustic impedance of the air. Accordingly, it is difficult to reproduce the low frequency range, making it difficult to realize sound quality from low frequency to high frequency. To solve this problem, a structure in which a plurality of through-holes are formed in a piezoelectric device is used. The through-holes are formed by forming a green sheet laminate of a piezoelectric device and then arranging it in various shapes and sizes. However, the piezoelectric device having a plurality of through-holes has a problem in that cracks are formed in the laminate during the sintering process. Cracks are caused by the destruction of the area around the through-hole as the green sheet laminate shrinks during the sintering process.

FIG. 1 is an image of a conventional piezoelectric device having through-hole. Referring to FIG. 1, in order to manufacture the conventional piezoelectric device, one or more through-holes are formed in the laminate as shown in (a), and then, when the sintering process is performed, destruction of laminate is occurred by the shrinkage.

In particular, as shown in (b), when through-hole having a large size is formed at the periphery or at the end region of the laminate, it is likely to be destroyed.

### DISCLOSURE

### Technical Problem

The present inventive concept is directed to providing piezoelectric speaker comprising piezoelectric device having one or more through-holes.

The present inventive concept is directed to providing a method of manufacturing the piezoelectric speaker comprising piezoelectric device having one or more through-holes.

### Technical Solution

One aspect of the present inventive concept provides a piezoelectric speaker comprising: a piezoelectric device having a stacked body having one or more through-holes formed in a direction from an upper surface to a lower surface, and electrodes formed in the stacked body; an adhesive layer disposed on a lower surface of the piezoelectric device; and a diaphragm attached to the piezoelectric device by the adhesive layer, wherein the one or more through-holes of the piezoelectric device are arranged symmetrically with respect to the center of the piezoelectric device.

The through-holes are arranged to decrease in size as the distance from the center of the piezoelectric device increases.

Each of the through-holes has a curved inner surface.

The electrodes are disposed on an upper surface, a lower surface of the piezoelectric device, and inside of the stacked body.

The through-holes pass through the electrodes disposed on the upper surface, the lower surface of the piezoelectric device, or the inside of the stacked body.

Another aspect of the present inventive concept provides a method of manufacturing a piezoelectric speaker, the method comprising: manufacturing a piezoelectric device having through-holes formed therein and having an electrode on the upper surface, the lower surface, or therein; and attaching the piezoelectric device and a diaphragm using an adhesive layer, wherein the through-holes are formed in the direction of the lower surface from the upper surface of the piezoelectric device, are arranged to decrease in size as the distance from the center increases, and are symmetrically arranged with respect to the center of the piezoelectric device.

the manufacturing the piezoelectric device includes manufacturing green sheet by using a slurry; forming through-holes at the green sheet; forming a stacked body by stacking the green sheets; and sintering the stacked body.

The other aspect of the present inventive concept provides a method of manufacturing a piezoelectric speaker, the method comprising: manufacturing a green sheet by using slurry having a piezoelectric ceramic powder, a dispersant, solvent and organic binder; forming holes and internal electrode at the green sheet; forming a stacked body in which the green sheets are stacked; sintering the stacked body; forming external electrode at the stacked body; and performing a poling the stacked body with high voltage.

The holes respectively connected in the vertical direction to pass through the stacked body.

The holes are arranged symmetrically with respect to the central portion of the stacked body.

The holes are arranged to decrease in size as distance from the center of the stacked body increases.

The holes are arranged avoiding the internal electrode.

The holes are filled with epoxy or a mixture of epoxy and hollow glass balls.

### Advantageous Effects

According to the present inventive concept, through-holes formed in the piezoelectric device have a large size in the center and a small size in the periphery away from the center, so that the possibility of cracking during the sintering process is greatly reduced. Furthermore, since the through-holes are symmetrically arranged with respect to the central portion, they are contracted at a uniform shrinkage rate as a whole, so that cracks and fractures are less likely to occur after sintering. Furthermore, by forming the edge portion of the inner surface of the through-hole into a curved shape, the inner surface edge portion is fundamentally prevented from becoming a crack generation point.

### DESCRIPTION OF DRAWINGS

FIG. 1 is an image of a conventional piezoelectric device having through-hole.

FIG. 2 is a cross-sectional view illustrating a piezoelectric speaker according to a preferred embodiment of the present inventive concept.

FIG. 3 is a cross-sectional view illustrating a piezoelectric device and electrodes according to a preferred embodiment of the present inventive concept.

FIG. 4 is a plane view showing a piezoelectric element according to a preferred embodiment of the present inventive concept.

FIGS. 5 and 6 are images of a laminate for a piezoelectric device according to a preferred embodiment of the present inventive concept.

FIG. 7 is a flowchart illustrating a method of manufacturing a piezoelectric speaker according to a preferred embodiment of the present inventive concept.

FIG. 8 is a view showing performance test results of a piezoelectric speaker according to a preferred embodiment of the present inventive concept and a piezoelectric speaker of another company.

### DETAILED DESCRIPTION

Hereinafter, embodiments of the present inventive concept will be described in detail with reference to the accompanying drawings. In describing the embodiment of the present inventive concept, if it is determined that a detailed description of a related known function or configuration makes the subject matter of the present inventive concept unclear, the detailed description thereof will be omitted.

FIG. 2 is a cross-sectional view illustrating a piezoelectric speaker according to a preferred embodiment of the present inventive concept.

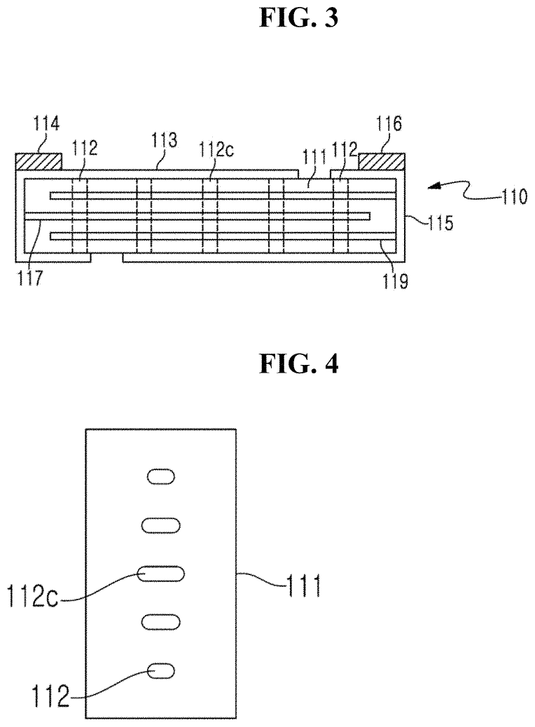

FIG. 3 is a cross-sectional view illustrating a piezoelectric device and electrodes according to a preferred embodiment of the present inventive concept.

FIG. 4 is a plane view showing a piezoelectric element according to a preferred embodiment of the present inventive concept.

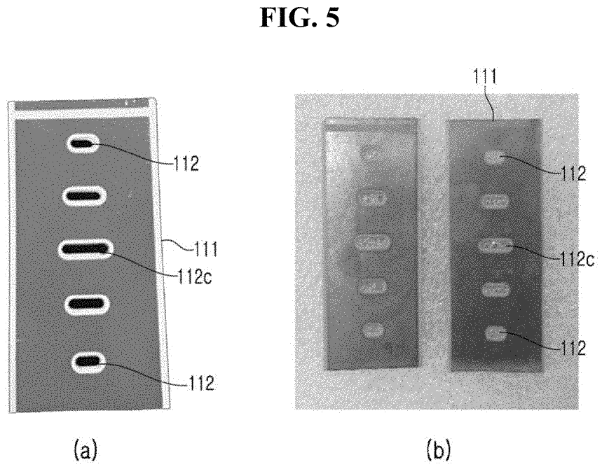

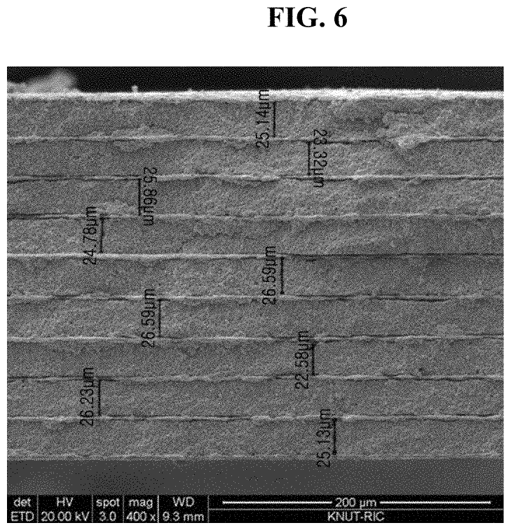

FIGS. 5 and 6 are images of a laminate for a piezoelectric device according to a preferred embodiment of the present inventive concept.

Referring to FIG. 2 to FIG. 6, the piezoelectric speaker 10 according to the preferred embodiment of the present inventive concept includes a piezoelectric device 110, an adhesive layer 130, and a diaphragm 150.

The piezoelectric device 110 includes a stacked body 111 and electrodes 113, 115, 117 and 119, and the stacked body 111 is provided with one or more through-holes 112. Preferably, the one or more through-holes 112 may be arranged to decrease in size as the distance from the center to the periphery increases. For reference, in the drawings, the through-hole disposed in the center is referred to as 112C. In addition, the one or more through-holes 112 may be arranged symmetrically with respect to the center, for example, may be arranged symmetrically on both sides around the through-hole 112C having the largest size. Also preferably, each of the through-holes 112 may have a curved shape at the edge of the inner surface.

Hereinafter, each element of the present inventive concept will be described in more detail.

The piezoelectric device 110 includes a stacked body 111 in which a plurality of piezoelectric layers are stacked. In addition, internal electrodes 117, 119 may be disposed on the piezoelectric layers. Internal electrodes 117, 119 and piezoelectric layers may be alternately stacked. The internal electrodes 117, 119 may be a positive internal electrode 117 and a negative internal electrode 119, and the positive internal electrode 117 and the negative internal electrode 119 are alternately formed on piezoelectric layers.

The internal electrodes 117, 119 may be made of a metal material having good conductivity, and may be made of a metal material containing Ag or Pd. The internal electrodes 117, 119 may be formed on the piezoelectric layer by a screen printing method or the like. These internal electrodes 117, 119 have function as an anode and a cathode in the stacked body 111, and these internal electrodes 117, 119 may be stacked alternately with the piezoelectric layer to form the piezoelectric device 110 having a polarity.

In addition, the internal electrodes 117, 119 disposed between each piezoelectric layers of the stacked body 111 are electrically connected to each internal electrodes 117 and 119 having the same polarity while alternately forming positive and negative electrodes and, the internal electrodes 117 and 119 having specific polarity may be electrically connected through the upper electrode 113 and the lower electrode 115 formed on the upper and lower portions of the stacked body 111.

When the piezoelectric layer is stacked, a piezoelectric layer in which the internal electrodes 117 and 119 is not formed may be additionally stacked on the uppermost layer to protect the exposed internal electrodes 117 and 119.

As described above, one or more through-holes 112 having a predetermined diameter passing through the piezoelectric device 110 are formed in the piezoelectric device 110.

When there are a plurality of through-holes 112 of the piezoelectric device 110 employed in the piezoelectric speaker 10 according to a preferred embodiment of the present inventive concept, the largest-sized through-hole 112C is disposed in the center, and the size of the through-hole is arranged to decrease as it goes away from the center. The stacked body 111 of the piezoelectric layer shrinks by sintering, and usually exhibits a shrinkage rate of about 20%. When the shrinkage occurs, it shrinks toward the center surface of the stacked body 111, and the distance to be moved by sintering shrinkage increases as it moves away from the center. Since the sintering shrinkage is caused by necking and coarsening among the piezoelectric ceramic particles constituting the stacking body 111, the driving force for shrinkage around the through-hole 112 decreases as the size of the through-hole 112 increases. As the distance from the center of the piezoelectric device 110 increases, the distance to be moved due to the shrinkage increases, so that the driving force for the shrinkage should be increased. Accordingly, as the distance from the center of the piezoelectric device 110 increases, the size of the through-hole 112 should decrease.

In addition, the piezoelectric device 110 employed in the piezoelectric speaker 10 of the present inventive concept may be symmetrically arranged around the through-hole 112C disposed at the center. If one or more through-holes 112 are asymmetrically formed, a difference in shrinkage ratio between regions of the stacked body 111 having the center of the piezoelectric device 110 as a symmetric point may occur, and this difference in shrinkage may cause sintering failure. Therefore, as shown, both sides may be symmetrical with respect to the largest through-hole 112C disposed in the center.

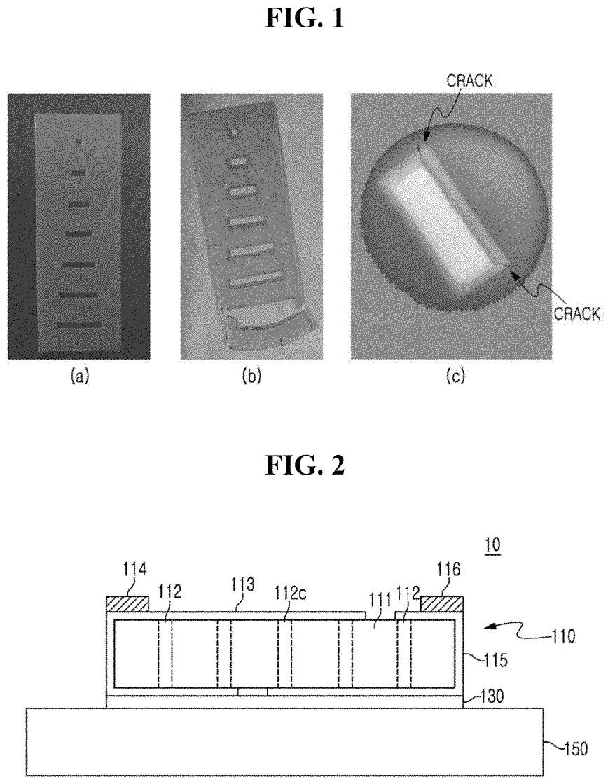

In addition, the through-holes 112 of the piezoelectric device 110 employed in the piezoelectric speaker 10 of the present inventive concept may have a curved shape at the corner of the inner surface. As shown in (c) of FIG. 1, the through-hole of the conventional piezoelectric device has a problem in that cracks occur at angled corners. In the present inventive concept, the through-holes 112 have a curved inner surface so that cracks do not occur in the corresponding portion even when the shrinkage process is performed. A curved inner edge includes shapes that do not include angled edges, such as an ellipse or a rectangular circle.

In addition, one or more through-holes 112 may pass through the stacked body 111 of the piezoelectric layer and the electrodes 113, 115, 117, 119. In addition, the interior of one or more through-holes 112 may be empty and may be formed to be in contact with air, or may be filled using a polymer resin in the through-holes 112 for impedance matching between air and the piezoelectric device 110. That is, the one or more through-holes 112 may be filled with any one of an epoxy-based resin, an acrylic resin, a silicone-based resin and a rubber, or may be filled with glass bead and any one of an epoxy-based resin, an acrylic resin, a silicone-based resin and a rubber. When the resin is filled in the through-hole 112, a damping effect is induced and resonance is suppressed, so that sound pressure can be constantly generated without peak or deep for each frequency.

Alternatively, the one or more through-holes 112 may be disposed avoiding the electrodes 113, 115, 117, 119 so as not to penetrate the electrodes 113, 115, 117, 119.

As shown in FIGS. 2 and 3, the upper electrode 113 and the lower electrode 115 are respectively formed in the vertical direction at the opposite end surfaces of the piezoelectric device 110, and each of the both ends may be formed in a structure disposed on the outer edges of the plurality of stacked piezoelectric layers. In particular, the upper electrode 113 is electrically shorted with a portion 117 of the inner electrode, and the remaining portion 119 of the inner electrode are electrically shorted with the lower electrode 115.

The upper electrode 113 and the lower electrode 115 are disposed outside the piezoelectric layer to perform a function of applying power from the outside. For example, the upper electrode 113 and the lower electrode 115 are formed by screen printing method using an electrode material containing Ag and glass.

In addition, the first lead terminal 114 is formed on the surface of the upper electrode 113, and the second lead terminal 116 is formed on the surface of the lower electrode 115. Accordingly, the upper electrode 113 and the lower electrode 115 may be electrically connected to an external power source through the respective lead terminals 114, 115.

That is, when an AC voltage is applied to each of the lead terminals 114 and 115, the AC voltage is applied to the upper electrode 113 and the lower electrode 115 connected to the lead terminals 114, 115, and the external power source is electrically connected to the piezoelectric device 110 through the internal electrodes 117, 119 respectively connected to the upper electrode 113 and the lower electrode 115. The shape deformation of the piezoelectric device 110 is generated by the transmitted external power, and displacement occurs in the diaphragm 150 to generate sound as the shape deformation of the piezoelectric device 110 is transmitted to the diaphragm 150.

The adhesive layer 130 may be formed on the lower part of the piezoelectric device 110 or the upper part of the diaphragm 150. Silicone epoxy, thermosetting resin, etc. may be used as a material for the adhesive layer 130, and the piezoelectric device 110 and the diaphragm 150 may be attached to each other by the adhesive layer 130.

The diaphragm 150 acoustically converts a mechanical signal generated by an electrical signal applied to the piezoelectric device 110, and the piezoelectric device 110 is fixed to the diaphragm 150 by the adhesive layer 130.

The diaphragm 150 may have a thickness similar to that of the piezoelectric device 110, or may have a thicker thickness than the piezoelectric device 110, and may be made of a flexible and highly elastic material. As an example, it may be made of a material obtained by mixing or synthesizing a polymer such as rubber, silicone, urethane and the like, and a nanostructure material such as carbon nanotubes and graphene.

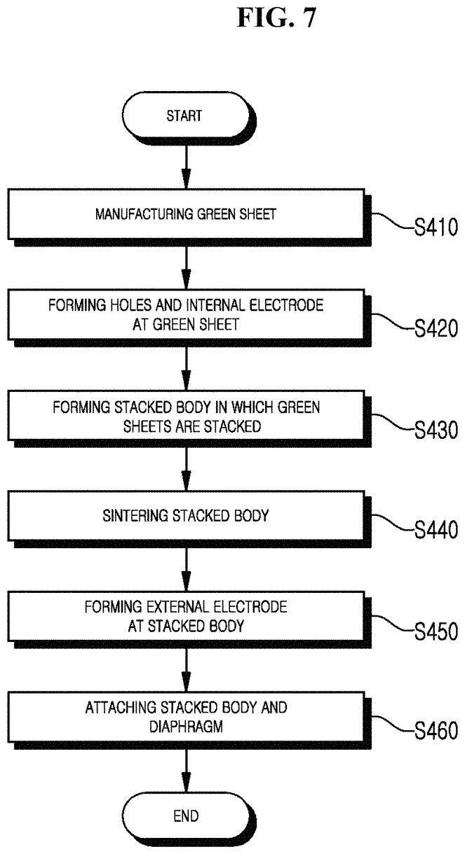

Hereinafter, a method of manufacturing a piezoelectric speaker according to a preferred embodiment of the present inventive concept will be described with reference to FIG. 7.

FIG. 7 is a flowchart illustrating a method of manufacturing a piezoelectric speaker according to a preferred embodiment of the present inventive concept.

The method of manufacturing a piezoelectric speaker according to the present inventive concept comprises the steps of manufacturing a green sheet using a slurry (S410), forming one or more holes and internal electrodes in the green sheets (S420), forming stacked body 111 in which the green sheets are stacked (S430), sintering the stacked body 111 having the through-hole 112 formed therein (S440), forming the upper electrode 113 or lower electrode 115 as an external electrode on the sintered stacked body 111 (S450), and attaching the stacked body 111 to a diaphragm 150 using the adhesive layer 130 (S460).

In the step of manufacturing the green sheet using the slurry (S410), a slurry for tape casting is made using lead zirconate titanate (PZT) powder. The slurry may be manufactured through lamination, punching, and sintering processes after tape casting. In addition to the raw material powder, a solvent, a dispersant, a binder, or a plasticizer may be added to the slurry. In this embodiment, the solvent is ethanol or toluene, the dispersant may be BYK2001, the binder may be PVB (polyvinyl butyral), and the plasticizer may be DOP (di-octyl-phthalate). The solids concentration of the slurry is 50% and the dispersant is used by weight of about 1% of the solids. A green sheet is manufactured using the above-described slurry using a doctor blade method, a coma coater, or a die coater. The green sheet is casted to a width of 20 cm, and the drying temperature is about 80° C.

In step 420, one or more holes and internal electrodes 117, 119 are formed in the green sheets prepared above. The formation of one or more holes and the internal electrodes 117, 119 does not matter even if the order is changed. The one or more holes may be formed to pass through the internal electrodes 117, 119 or not to penetrate the internal electrodes 117, 119. An electrode paste containing Ag and Pd as materials of the internal electrodes 117, 119 is deposited on the green sheet using screen printing method.

In addition, the one or more through-holes 112 may be arranged to form a through-hole 112C having the largest size in the central portion, and to decrease in size toward the periphery or away from the center. In addition, as described above, the through-holes 112 may have a curved shape at the inner surface of the through-holes 112.

In step 430, a step of stacking green sheets to form a stacked body 111 is performed. The electrode paste is applied and green sheets having one or more holes formed therein are stacked. Since the internal electrodes form a positive electrode and a negative electrode in the stacked body 111, a piezoelectric device having a polarity may be configured. In addition, one or more holes are connected in a vertical direction to pass through the stacked body.

Subsequently, the stacked body 111 in which the through-holes 112 are formed is degreased, for example, at 500° C. in the air for 1 hour, and is fired at, for example, 1100° C. in the air for 3 hours (S440). A crack-free stacked body 111 may be obtained by the arrangement of the through-holes 112 described above.

Next, the step of forming the upper electrode 113 or the lower electrode 115 on the sintered stacked body 111 is performed (S450). In order to form the lower electrode 115 and upper electrode 113, both end surfaces of the stacked body 111 in the longitudinal direction (x) are cut, the ends of the internal electrodes 117 and 119 are exposed, and the side surfaces of the stacked body 111 are exposed, and the upper electrodes 113 and lower electrode 115 are formed on both main surfaces of the stacked body. An electrode paste containing Ag and glass as electrode materials is applied to one side of the main surface of the piezoelectric device 110 by a screen printing method.

After that, an electrode paste containing Ag and glass as an external electrode material is applied to both sides in the longitudinal direction (x) by dip coating and screen printing, and heat-treated at 700° C. in the air for 10 minutes to form a structure in which the upper electrode 113 and the lower electrode 115 are formed around the piezoelectric device 110 in which the hole is formed. In addition, the first lead terminal 114 is formed on the surface of the upper electrode 113, and the second lead terminal 116 is formed on the surface of the lower electrode 115. Accordingly, the upper electrode 113 and the lower electrode 115 may be electrically connected to an external power source through the respective lead terminals 114 and 116. By this step, the stacked body 111 has the shape of the piezoelectric device 110. Then, it is polled with a high voltage in order to give piezoelectricity to the sintered body.

Next, a step (S460) of attaching the piezoelectric element 110 to the diaphragm 150 using the adhesive layer 130 is performed. The diaphragm 150 may be made of, for example, a material obtained by synthesizing or mixing a polymer such as rubber, silicon, or urethane with a nanostructure material such as carbon nanotubes and graphene.

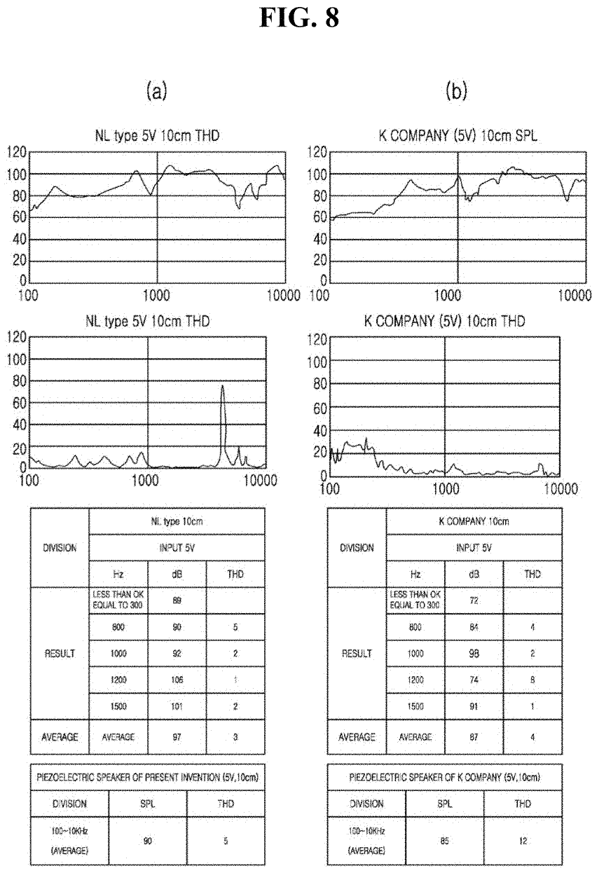

FIG. 8 is a view showing performance test results of a piezoelectric speaker according to a preferred embodiment of the present inventive concept and a piezoelectric speaker of another company.

FIG. 8(a) shows the piezoelectric speaker of the present inventive concept, and (b) shows the results for the piezoelectric speaker of K company. The two measured values are the values measured by a certified speaker manufacturer, and using the same measuring instrument, the sound pressure (SPL) and THD are measured in an anechoic chamber with a microphone 10 cm in front while applying an input voltage of 5 V from 100 Hz to 10 kHz. As shown in FIG. 8, it can be seen that the average value (average sound pressure at 800, 1000, 1200, and 1500 Hz) in the mid-bass portion of the piezoelectric speaker according to the present inventive concept is higher than 10 dB and the THD is also low. In addition, the overall average sound pressure of 100 Hz to 10 kHz is also 90 dB for the piezoelectric speaker according to the present inventive concept, but 85 dB for company K, the piezoelectric speaker according to the present inventive concept is superior by about 5 dB. It can be seen that the THD of the K company is 12 dB, while the THD of the present inventive concept is 5, which is significantly lower in sound distortion. In addition, the low-pitched sound region, which is pointed out as a disadvantage of the piezoelectric speaker, shows a high sound pressure as 89 dB at a low frequency of 150 Hz in the present inventive concept, whereas piezoelectric speaker of Company K shows a sound pressure of 72 dB at 430 Hz, which is about 17 dB lower than that of the present inventive concept. So, it shows that the piezoelectric speaker according to the present inventive concept can solve the problem of sound pressure loss in the mid-bass region, which is a disadvantage of the conventional piezoelectric speaker.

As mentioned above, although specific embodiments have been described in the detailed description of the present inventive concept, it will be apparent to those of ordinary skill in the art that various modifications are possible without departing from the scope of the present inventive concept.

1. A piezoelectric speaker comprising:
a piezoelectric device having a stacked body having one or more through-holes formed in a direction from an upper surface to a lower surface, and electrodes formed in the stacked body;
an adhesive layer disposed on a lower surface of the piezoelectric device; and
a diaphragm attached to the piezoelectric device by the adhesive layer,
wherein the one or more through-holes of the piezoelectric device are arranged symmetrically with respect to the center of the piezoelectric device.

2. The piezoelectric speaker of claim 1, wherein the through-holes are arranged to decrease in size as the distance from the center of the piezoelectric device increases.

3. The piezoelectric speaker of claim 1, wherein each of the through-holes has a curved inner surface.

4. The piezoelectric speaker of claim 1, wherein the electrodes are disposed on an upper surface, a lower surface of the piezoelectric device, and inside of the stacked body.

5. The piezoelectric speaker of claim 4, wherein the through-holes pass through the electrodes disposed on the upper surface, the lower surface of the piezoelectric device, or the inside of the stacked body.

6. A method of manufacturing a piezoelectric speaker, the method comprising:
manufacturing a piezoelectric device having through-holes formed therein and having an electrode on the upper surface, the lower surface, or therein; and
attaching the piezoelectric device and a diaphragm using an adhesive layer,
wherein the through-holes are formed in the direction of the lower surface from the upper surface of the piezoelectric device, are arranged to decrease in size as the distance from the center increases, and are symmetrically arranged with respect to the center of the piezoelectric device.

7. The method of claim 6, wherein the manufacturing the piezoelectric device includes:
manufacturing green sheet by using a slurry;
forming through-holes at the green sheet;
forming a stacked body by stacking the green sheets; and
sintering the stacked body.

8. A method of manufacturing a piezoelectric speaker, the method comprising:
manufacturing a green sheet by using slurry having a piezoelectric ceramic powder, a dispersant, solvent and organic binder;
forming holes and internal electrode at the green sheet;
forming a stacked body in which the green sheets are stacked;
sintering the stacked body;
forming external electrode at the stacked body; and
performing a poling the stacked body with high voltage.

9. The method of claim 8, wherein the holes respectively connected in the vertical direction to pass through the stacked body.

10. The method of claim 9, wherein the holes are arranged symmetrically with respect to the central portion of the stacked body.

11. The method of claim 9, wherein the holes are arranged to decrease in size as distance from the center of the stacked body increases.

12. The method of claim 9, wherein the holes are arranged avoiding the internal electrode.

13. The method of claim 9, wherein the holes are filled with epoxy or a mixture of epoxy and hollow glass balls.
